(19) United States
(12) Patent Application Publication
(10) Pub. No.: US 2025/0234619 A1
(43) Pub. Date: Jul. 17, 2025

(54) Power Semiconductor Device Having Improved Transient Handling Without Field Insulating Layer

(71) Applicant: Wolfspeed, Inc., Durham, NC (US)

(72) Inventors: Edward Robert Van Brunt, Cary, NC (US); Adam Benjamin Barkley, Chapel Hill, NC (US); In-Hwan Ji, Apex, NC (US); Thomas Edgar Harrington, III, Durham, NC (US)

(21) Appl. No.: 18/412,190

(22) Filed: Jan. 12, 2024

(51) Int. Cl. H01L 29/417; H01L 29/16; H01L 29/78

(52) U.S. Cl. CPC H10D 64/252; H10D 30/66; H10D 62/8325

(57) ABSTRACT

Power semiconductor devices are provided. In one example, a power semiconductor device includes a semiconductor structure. The power semiconductor device further includes a polysilicon gate layer on the semiconductor structure in an inactive region of the semiconductor device. The power semiconductor device further includes a gate insulating pattern between the polysilicon gate layer and the semiconductor structure, the gate insulating pattern having a thickness such that a distance between the semiconductor in the inactive region and the polysilicon gate layer through the gate insulating pattern is less than about 100 nm. The power semiconductor device further includes a shunt contact structure on semiconductor structure in the inactive region. A gate insulating electric field across the gate insulating pattern associated with a displacement current is less than about 8 MV/cm.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or gallium nitride (“GaN”) based semiconductor materials.

### SUMMARY

Aspects and advantages of embodiments of the present disclosure will be set forth in part in the following description, or may be learned from the description, or may be learned through practice of the embodiments.

One example aspect of the present disclosure is directed to a power semiconductor device. The power semiconductor device includes a semiconductor structure. The power semiconductor device further includes a polysilicon gate layer on the semiconductor structure in an inactive region of the semiconductor device. The power semiconductor device further includes a gate insulating pattern between the polysilicon gate layer and the semiconductor structure, the gate insulating pattern having a thickness such that a distance between the semiconductor in the inactive region and the polysilicon gate layer through the gate insulating pattern is less than about 100 nm. The power semiconductor device further includes a shunt contact structure on semiconductor structure in the inactive region, the shunt contact structure providing a path for a displacement current from a drain contact to a source contact through the semiconductor structure in the inactive region. The gate insulating electric field across the gate insulating pattern associated with the displacement current is less than about 8 MV/cm.

Another example aspect of the present disclosure is directed to a power semiconductor device. The power semiconductor device includes a semiconductor structure. The power semiconductor device further includes a polysilicon gate layer on the semiconductor structure in an inactive region of the power semiconductor device. The power semiconductor device further includes a gate pad coupled to the polysilicon gate layer. The power semiconductor device further includes an inter metal dielectric (IMD) layer between at least a portion of a gate pad and the semiconductor structure in the inactive region. The IMD layer directly contacts at least a portion of the gate pad and at least a portion of the semiconductor structure in the inactive region.

Another example aspect of the present disclosure is directed to a power semiconductor device. The power semiconductor device includes a semiconductor structure, wherein a portion of the semiconductor structure is in an inactive region of the power semiconductor device. The power semiconductor device further includes a polysilicon gate layer on the semiconductor structure in the inactive region. The power semiconductor device further includes a gate insulating pattern between the polysilicon gate layer and the semiconductor structure in the inactive region. The power semiconductor device further includes a shunt contact structure on semiconductor structure, the shunt contact structure providing a path for a displacement current from a drain contact to a source contact. The polysilicon gate layer is located in a region proximate the shunt contact structure such that a gate insulating electric field resulting from the displacement current is less than about 8 MV/cm.

Another example aspect of the present disclosure is directed to a power semiconductor device. The power semiconductor device includes a semiconductor structure. The power semiconductor device further includes a polysilicon gate layer in an inactive region of the power semiconductor device. The power semiconductor device further includes a gate insulating pattern between the polysilicon gate layer and the semiconductor structure in the inactive region. The semiconductor structure comprises a silicide contacting the gate insulating pattern in the inactive region.

Another example aspect of the present disclosure is directed to a power semiconductor device. The power semiconductor device includes a semiconductor structure. The power semiconductor device further includes a polysilicon gate layer. The power semiconductor device further includes a gate insulating pattern between the polysilicon gate layer and the semiconductor structure. The power semiconductor device further includes a source bus coupled to the polysilicon gate layer. The gate insulating pattern comprises a plurality of holes. A conductive path in one or more of the plurality of holes connecting the semiconductor structure with the polysilicon gate layer.

Another example aspect of the present disclosure is directed to a power semiconductor device. The power semiconductor device includes a semiconductor structure. The power semiconductor device further includes a polysilicon gate layer. The power semiconductor device further includes a gate insulating pattern between the polysilicon gate layer and the semiconductor structure. The power semiconductor device further includes a shunt contact structure, the shunt contact structure providing a path for a displacement current from a drain contact to a source contact. There is no field insulating layer having a thickness of greater than 100 nm between the polysilicon gate layer and the semiconductor structure.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a plan view of a semiconductor wafer that includes a plurality of semiconductor devices according to example embodiments of the present disclosure.

FIG. 2A depicts a plan view of one of the semiconductor devices included on the semiconductor wafer of FIG. 1 according to example embodiments of the present disclosure.

FIG. 2B depicts a plan view of the semiconductor device of FIG. 2A according to example embodiments of the present disclosure with the source pad and gate pad metallization removed.

FIGS. 3A and 3B depict a portion of a unit transistor cell of the power semiconductor device of FIGS. 2A-2B according to example embodiments of the present disclosure.

FIG. 4 depicts a cross-sectional view of an example semiconductor device including a field insulating layer with defect according to example embodiments of the present disclosure.

FIG. 5 depicts a cross-section of at least a portion of an example power semiconductor device according to example embodiments of the present disclosure.

FIGS. 6A-6D depict views of at least a portion of an example power semiconductor device including interdigitated vias according to example embodiments of the present disclosure.

FIG. 7 depicts a cross-section of at least a portion of an example power semiconductor device including a silicide according to example embodiments of the present disclosure.

FIG. 8 depicts a cross-section of at least a portion of an example power semiconductor device including a source bus according to example embodiments of the present disclosure.

FIGS. 9A and 9B depict a plan view of metal layers of a portion of a semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

A power semiconductor device may have a semiconductor substrate, such as a silicon carbide substrate having a first conductivity type (e.g., an n-type substrate), on which an epitaxial layer structure having the first conductivity type (e.g., n-type) is formed. A portion of this epitaxial layer structure (which may include one or more separate layers) functions as a drift region of the power semiconductor device. The device typically includes an “active region,” which includes one or more unit cell devices that have a junction such as a p-n junction. The active region may be formed on and/or in the drift region. The active region acts as a main junction for blocking voltage in the reverse bias direction and providing current flow in the forward bias direction. The power semiconductor devices may have a unit cell structure in which the active region of each power semiconductor device includes a plurality of individual unit cell devices that are electrically connected in parallel and that together function as a single power semiconductor device.

Power semiconductor devices are often fabricated from wide bandgap semiconductor materials, such as silicon carbide or Group Ill-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure, or vice versa. Herein, the term “semiconductor structure” refers to a structure that includes one or more semiconductor layers, such as semiconductor substrates and/or semiconductor epitaxial layers.

Vertical power semiconductor devices, including vertical MOSFETs, can have a standard gate electrode design in which the gate electrode of the transistor is formed on top of the semiconductor structure. Alternatively, the power semiconductor devices may have the gate electrode in a gate trench within the semiconductor structure. Power semiconductor devices having trench gate electrodes are typically referred to as trench gate devices (e.g., trench gate MOSFETs). With the standard gate electrode design, the channel region of each unit cell transistor is horizontally disposed underneath the gate electrode. In contrast, in the trench gate design, the channel is vertically disposed.

Power silicon carbide MOSFETs are in use today for applications requiring high voltage blocking such as voltage blocking of 300 V or more. By way of example, silicon carbide MOSFETs are commercially available that are rated for current densities of 10 A/cm² or more that will block voltages of at least 10 kV. To form such devices, a plurality of unit cells are formed, where each unit cell includes a MOSFET transistor. In high power applications, a large number of these unit cells (e.g., hundreds or thousands) are typically provided on a single semiconductor substrate, and a gate structure (e.g., gate electrode pattern) is formed on a top side of the semiconductor substrate that acts as the gate electrode for all of the unit cells. The opposite (bottom) side of the semiconductor substrate acts as a common drain for all of the unit cells of the device. A plurality of source contacts are formed on source regions in the semiconductor structure that are exposed within openings in the gate electrode pattern. These source contacts are also electrically connected to each other to serve as a common source. The resulting device has three terminals, namely a common source terminal, a common drain terminal and a common gate electrode that act as the terminals for the hundreds or thousands of individual unit cell transistors. It will be appreciated that the above description is of an n-type MOSFET; the locations of the drain and source may be reversed for a p-type MOSFET.

The gate structure (e.g., gate electrode pattern) of a power MOSFET may be implemented by forming a patterned conductive layer on the semiconductor structure. The patterned conductive layer may include, for instance, a gate pad (or gate contact), one or more gate runners (e.g., gate buses), and a plurality of elongated gate fingers that extend through an active region of the device. In some examples, the patterned conductive layer may include a semiconductor layer such as, for example, a polysilicon gate layer. The gate pad may be in an inactive region of the device, and each gate finger may connect to the gate pad, either directly or via one or more of the gate runner(s).

In some cases, the gate pad portion of the gate structure may be formed on a thick field insulating layer. The field insulating layer may include, for example, a field oxide layer (e.g., a silicon oxide layer), although other insulating materials or a combination of insulating materials may be used. A metal gate bond pad may be formed on top of a portion of the gate pad and may form an ohmic contact to the gate pad. Bond wires may be attached to the gate bond pad to provide a mechanism for applying a bias voltage to the gate structure of the device.

As discussed above, the gate structure and the metal layers/bond pads for the source, gate and drain are formed on a semiconductor structure. The semiconductor structure has an active region in which the unit cell transistors are formed and an inactive region. The inactive region may include a gate pad portion that is underneath the above-discussed gate bond pad and field insulating layer, a gate runner portion that is underneath the above-discussed gate runners and field insulating layer, and a termination portion (e.g., edge termination portion) that may surround the active region. The gate pad portion of the inactive region of the semiconductor structure that is underneath the gate pad and field insulating layer may include an implanted region in an upper surface of the semiconductor structure. For example, in an n-type MOSFET, a large p-type silicon carbide region is formed, for instance, using ion implantation in the upper surface of the semiconductor layer structure to form the inactive region. Thereafter, the field insulating layer is formed on this p-type silicon carbide region. During operation, the MOSFET may switch from reverse blocking state (where the device may block a very large voltage and not conduct current) to the on-state (where the device may conduct large currents) in a very short period of time. As the device switches states, a displacement current is generated that flows between the drain terminal on the bottom surface of the device and the source terminal on the upper surface of the device (in an n-type device).

Furthermore, at the edge of field insulating layer, a thin gate insulating pattern may be provided between the gate electrode pattern and the implanted region of the semiconductor layer structure. This gate insulating pattern may include, for example, a silicon oxide pattern, although other insulating materials may be used. The gate insulating pattern may be between the source contacts and the field insulating layer, and hence the displacement current generated in the portion of the inactive region beneath the gate structure may flow underneath the gate insulating pattern. This gate insulating pattern may be much thinner than the field insulating layer, having a thickness of less than about 100 nm, such as less than about 50 nm, such as between about 35 nm to about 50 nanometers.

In some instances, the displacement current may flow in the active region of the semiconductor structure and in the inactive region (e.g., beneath the gate structure) of the semiconductor structure. In each case, the magnitude of the displacement current (IDisp) is the product of the change in voltage per unit time (dV/dt) across the p-n junction in the semiconductor layer structure and the capacitance of this p-n junction (Cpn). In other words:

IDisp=(dV/dt)*Cpn

In the active region, there are many paths for the displacement current (since each unit cell includes a pair of source contacts) and the p-n junctions are small (since a width in the horizontal direction of each p-well that forms a p-n junction with an underlying n-type layer may only be, for example, about 2 to about 3 microns). As such, the capacitance of the p-n junctions in the active region may be relatively small, reducing the magnitude of the displacement current in the active region. However, in the portion of the inactive region beneath the gate structure (e.g., gate pad), the above-discussed p-type silicon carbide region that is formed underneath the field insulating layer may have a length (in horizontal direction) of, for example, about 100 microns to about 300 microns, and the displacement current generated in this region must flow to the source contacts of the unit cells closest to the portion of the inactive region of the semiconductor structure beneath the gate structure. As such, the capacitance of the p-n junction in the inactive region underneath the gate structure may be much larger, resulting in a significantly larger displacement current.

When the displacement current flows, a voltage is generated in the implanted region of the semiconductor structure. Pursuant to Ohm's law, a value of this voltage is equal to the product of the displacement current and the resistance of the semiconductor structure along the displacement current path. In silicon carbide-based semiconductor structures, implanted regions tend to have high sheet resistance. In the portion of the inactive region beneath the gate structure, the resistance may be high due to the implanted region underneath the field insulating layer and the capacitance of the p-n junction may be high for the reasons discussed above. As such, the displacement current flowing in the portion of the inactive region beneath the gate structure may generate high voltages in the semiconductor structure during device operation.

The field insulating layer and the gate insulating layer can prevent the displacement current from damaging portions of the inactive region below the gate pad. However, although the inclusion of a field insulating layer and a gate insulating layer can provide some resilience against displacement currents, this approach may suffer from some drawbacks. For instance, in the event of a defect in the field insulating layer, where a portion of the field insulating layer is either missing or relatively thin (e.g., due to a manufacturing variation), the defect in the field insulating layer can contribute to premature failure at reduced displacement currents. For instance, the power semiconductor device may experience breakdown within normal operating conditions due to defects in the field insulating layer. Furthermore, even relatively minor defects, such as submicron-level defects, may contribute to premature breakdown of the power semiconductor device. In this way, the inclusion of the field insulating layer introduces a potential vulnerability in the power semiconductor device that may contribute to suboptimal performance of the power semiconductor device and/or reduced manufacturing yields of power semiconductor devices capable of performing over all rated conditions.

According to example aspects of the present disclosure, however, a power semiconductor device can incorporate a gate pad structure and other gate structures that are robust to transient currents, such as displacement currents caused by voltage changes during switching, without including a field insulating layer. The power semiconductor device according to example aspects of the present disclosure can include a semiconductor structure and a polysilicon gate layer on the semiconductor structure in an inactive region of the semiconductor device. A gate insulating pattern can be between the polysilicon gate layer and the semiconductor structure. The gate insulating pattern can have a thickness such that a distance between the semiconductor in the inactive region and the polysilicon gate layer through the gate insulating pattern is less than about 100 nm, such as less than about 50 nm, such as in a range of about 35 nm to about 50 nm. Furthermore, the power semiconductor device can include a shunt contact structure on semiconductor structure in the inactive region. The shunt contact structure can provide a path for a displacement current from a drain contact to a source contact through the semiconductor structure in the inactive region. In addition, the electric field across the gate insulating pattern between the polysilicon gate layer and the source contact is less than about 8 MV/cm, such as in a range of about 1.5 MV/cm to 7 MV/cm, such as in a range of about 5 MV/cm to 6 MV/cm, such as less than about 5.7 MV/cm. The electric field across the gate insulating pattern can be associated with the displacement current (e.g., or another transient current). Herein, the electric field across the gate insulating pattern in the inactive region between the semiconductor structure and the polysilicon gate layer will be referred to as the “gate insulating electric field.” For instance, in some implementations, the polysilicon gate layer is located in a region proximate the shunt contact structure such that the magnitude of the gate insulating electric field resulting from the displacement current is less than about 8 MV/cm, such as in a range of about 1.5 MV/cm to 7 MV/cm, such as in a range of about 5 MV/cm to about 6 MV/cm, such as less than about 5.7 MV/cm.

As another example, in some implementations, an inter metal dielectric (IMD) layer can be included between at least a portion of a gate pad and the semiconductor structure in the inactive region. The IMD layer directly contacts at least a portion of the gate pad and at least a portion of the semiconductor structure in the inactive region.

As another example, in some implementations, the semiconductor structure includes a silicide contacting the gate insulating pattern in the inactive region. As another example, in some implementations, the gate insulating pattern includes a plurality of holes and a conductive path in one or more of the plurality of holes connects the semiconductor structure with the polysilicon gate layer.

The example aspects of the present disclosure can provide for a number of technical effects and benefits. For instance the omission of the thick field insulating layer in the inactive region can remove a potential source of premature breakdown due to defects in the field insulating layer, which can provide for improved robustness of the power semiconductor device to transient currents. Furthermore, the power semiconductor device including the gate insulating pattern having a thickness less than about 100 nm and having a gate insulating electric field of less than about 8 MV/cm can be rated for similar or identical loads as power semiconductor devices including the thick field insulating layer while still providing improved robustness through the omission of the thick field insulating layer.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based transistor devices for purposes of illustration and discussion. Those of ordinary skill in the art, using the disclosures provided herein, will appreciate that certain aspects of the present disclosure may be applicable to other transistor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

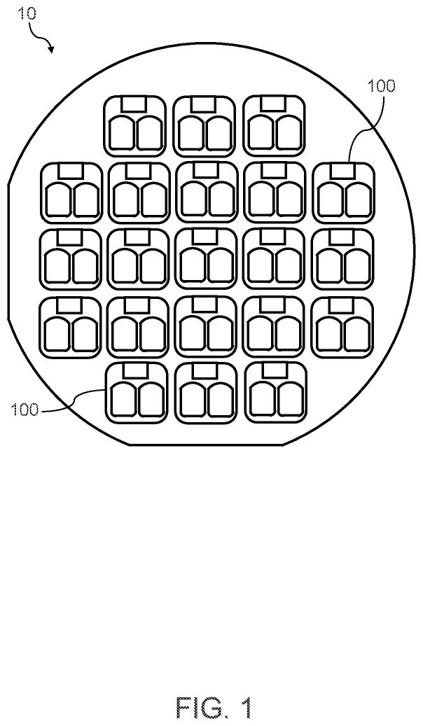

FIG. 1 is a plan view of a wafer 10 that includes a plurality of power semiconductor devices according to example embodiments of the present disclosure. Referring to FIG. 1, the wafer 10 may be a thin planar structure that includes a semiconductor structure with other material layers such as insulating layers and/or metal layers formed thereon. The semiconductor structure may include a semiconductor substrate and/or a plurality of other semiconductor layers. A plurality of semiconductor devices 100 may be formed in the wafer 10. The semiconductor devices 100 may be formed in rows and columns and may be spaced apart from each other so that the wafer 10 may later be subjected to a singulation process (e.g., diced) to separate the individual semiconductor devices 100 for packaging and testing. The wafer 10 may comprise a silicon carbide substrate having one or more silicon carbide layers formed thereon (e.g., by epitaxial growth) in some embodiments. Other semiconductor layers (e.g., polysilicon gate layers), insulating layers and/or metal layers may be formed on the silicon carbide semiconductor structure to form the power semiconductor devices 100. The silicon carbide substrate and the silicon carbide layers formed thereon may be 4H silicon carbide in some embodiments.

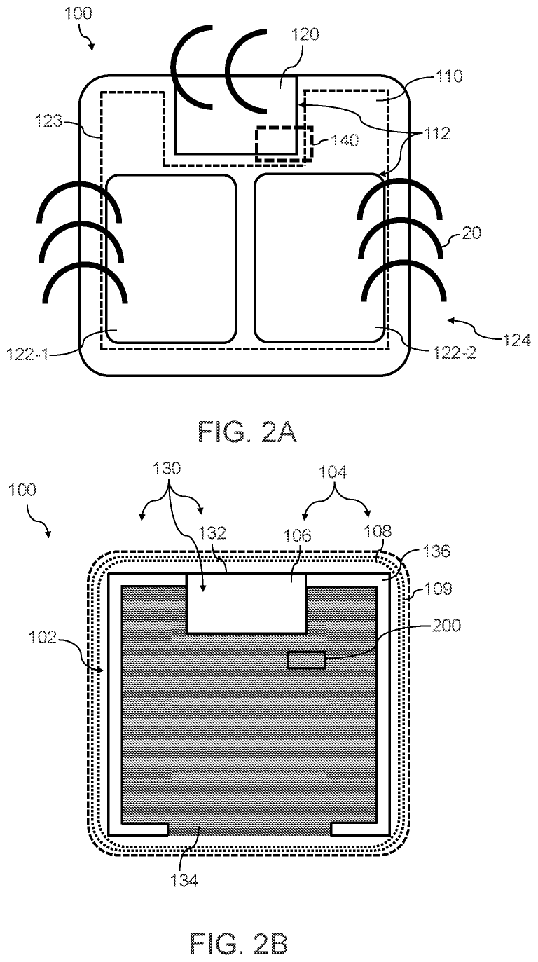

FIG. 2A is a plan view of one of the power semiconductor devices 100 included on the semiconductor wafer 10 of FIG. 1. FIG. 2B is a schematic plan view of the power semiconductor device 100 of FIG. 2A with the source and gate metallization removed. In the description below it is assumed that the power semiconductor device 100 is an n-type power MOSFET. However, those of ordinary skill in the art, using the disclosures provided herein, will understand that aspects of the present disclosure may be implemented in a p-type power MOSFET or other semiconductor device (e.g., IGBT, Schottky diode, etc.) without deviating from the scope of the present disclosure.

As shown in FIG. 2A, a protective layer 110 covers a substantial portion of the top surface of the power semiconductor device 100. The protective layer 110 may be formed, for example, of polyamide. Various bond pads may be exposed through openings 112 in the protective layer 110. The bond pads may include a gate bond pad 120 and one or more source bond pads 122. Two source bond pads 122-1, 122-2 are illustrated in FIG. 2A. While not visible in FIG. 2A, a drain bond pad 124 may be provided on the bottom side of the power semiconductor device 100. The bond pads 120, 122, 124 may be formed of a metal, such as aluminum, that bond wires can be readily attached to via techniques such as thermo-compression or soldering. The bond pads may be coupled to terminals in a semiconductor package to provide a gate terminal, source terminal, and drain terminal respectively for the semiconductor device. As will be discussed in more detail below, source contacts are provided that contact a semiconductor structure of the power semiconductor device 100. The source contacts may be lower portions of a source metal pattern 123 that extends across much of the upper surface of the power semiconductor device 100 (e.g., all but the portion of the upper surface of the power semiconductor device 100 occupied by the gate bond pad 120). The source bond pads 122-1, 122-2 may include portions of the source metal pattern 123 that are exposed by the openings 112 in the protective layer 110. Bond wires 20 are shown in FIG. 2A that may be used to connect the gate bond pad 120 and the source bond pads 122-1, 122-2 to external voltage sources (not shown) such as terminals of other circuit elements.

As is shown in FIG. 2B, the power semiconductor device 100 includes a semiconductor structure that includes an active region 102 and an inactive region 104. The active region 102 is an area of the device that includes operable transistors (e.g., the unit cell transistors discussed herein), while the inactive region 104 is an area that does not include such operable transistors. The unit cell transistors 200 of the power semiconductor device 100 are formed in the active region 102. The location of one unit cell 200 is shown by a box 200 in FIG. 2B to provide context. The active region 102 may generally correspond to the area under the source metal pattern 123 in some embodiments. The inactive region 104 includes a gate structure portion 106 and an edge termination portion 108. The gate structure portion 106 of the inactive region 104 may approximately correspond to the portion of the semiconductor structure that is underneath the certain portions of the gate structure of the semiconductor device. The edge termination portion 108 of the inactive region 104 may extend around a periphery of the power semiconductor device 100 and may include one or more termination structures such as guard rings and/or a junction termination extension that can reduce electric field crowding that may occur around the edge of the device. The termination structures (shown as guard rings 109) may spread out the electric fields along the periphery of the MOSFET, reducing electric field crowding. The edge termination structures may serve to increase the reverse blocking voltage at which a phenomenon known as “avalanche breakdown” occurs where an increasing electric field results in runaway generation of charge carriers within the semiconductor device, resulting in a sharp increase in current that may damage or even destroy the device.

As is further shown in FIG. 2B, a gate structure 130 (e.g., gate electrode pattern) may be provided that includes a gate pad 132, a plurality of gate fingers 134, and one or more gate runners 136 (e.g., gate buses) that electrically connect the gate fingers 134 to the gate pad 132. The gate pad 132 of the gate structure 130 may be underneath the gate bond pad 120. The gate runners 136 may include one or more peripheral gate runners on the inactive region 104. The gate runners 136 are peripheral gate runners that extend about or around at least a part of the peripheral portion of the semiconductor device 100. The gate fingers 134 may extend horizontally across the active region 102. An insulating layer (not shown) may cover the gate fingers 134 and gate runner(s) 136. The source metal pattern 123 may be provided over the gate fingers 134 and insulating layer, with the source contacts of the source metal layer contacting corresponding source regions in the semiconductor structure in openings between the gate fingers 134.

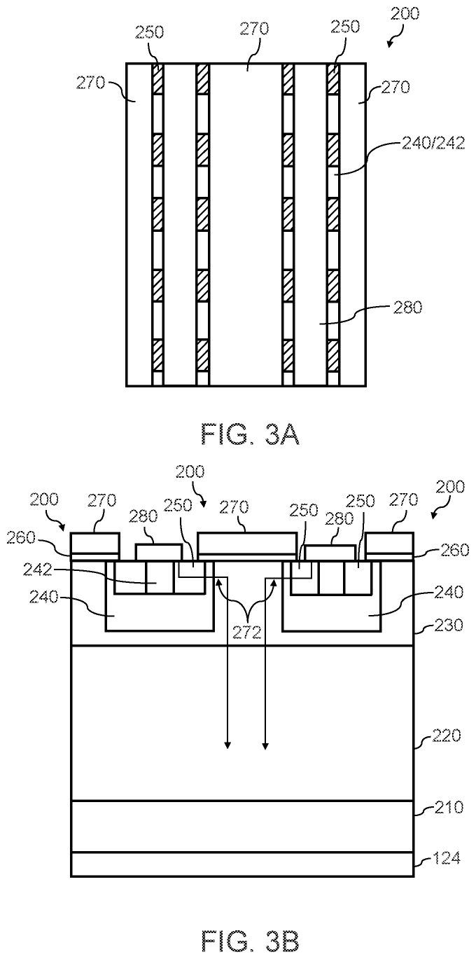

FIG. 3A is a schematic plan view of a portion of a unit cell 200 of the power semiconductor device 100 of FIGS. 2A-2B. It will be appreciated that the specific layer structure, doping concentrations, materials, conductivity types and the like that are shown in FIG. 3A and/or described below are merely provided as examples to illustrate in detail the structure of a specific example embodiment. Thus, the specific details discussed below are not limiting to the present disclosure.

As shown in FIGS. 3A and 3B, the power semiconductor device 100, and hence the unit cell 200, includes an n-type wide band-gap semiconductor substrate 210. The substrate 210 may include, for example, a single crystal 4H silicon carbide semiconductor substrate. The substrate 210 may be heavily-doped with n-type impurities (i.e., an n+ silicon carbide substrate). The impurities may comprise, for example, nitrogen or phosphorus. The doping concentration of the substrate 210 may be, for example, between 1×10¹⁸ atoms/cm³ and 1×10²¹ atoms/cm³, although other doping concentrations may be used. The substrate 210 may be any appropriate thickness (e.g., between 100 and 500 microns thick).

A lightly-doped n-type (n) silicon carbide drift region 220 is provided on the substrate 210. The n-type silicon carbide drift region 220 may be formed by, for example, epitaxial growth on the silicon carbide substrate 210. The n-type silicon carbide drift region 220 may have, for example, a doping concentration of 1×10¹⁶ to 5×10¹⁷ dopants/cm³. The n-type silicon carbide drift region 220 may be a thick region, having a vertical height above the substrate 210 of, for example, 3-100 microns. An upper portion of the n-type silicon carbide drift region 220 may comprise an n-type silicon carbide current spreading layer 230 in some embodiments. The n-type silicon carbide current spreading layer 230 may be grown in the same processing step as the remainder of the n-type silicon carbide drift region 220 and may be considered to be part of the n-type silicon carbide drift region 220. The n-type current spreading layer 230 may be a moderately-doped current spreading layer 230 that has a doping concentration (e.g., doping concentration of 1×10¹⁶ to 5×10¹⁸ dopants/cm³) that exceeds the doping concentration of the remainder of the more lightly-doped n-type silicon carbide drift layer 220. The n-type current spreading layer 230 may be omitted in some embodiments.

An upper portion of the n-type current spreading layer 230 may be doped p-type by ion implantation to form p-wells 240. The p-wells 240 may have a doping concentration of, for example, between 5×10¹⁶/cm³ and 5×10¹⁹/cm³. An upper portion 242 of each p-well may be more heavily doped with p-type dopants. The upper portion 242 of each p-well 240 may have a doping concentration of, for example, between 2×10¹⁸/cm³ and 1×10²⁰/cm³. The p-wells 240 (including the more heavily-doped upper portions 242 thereof) may be formed by ion implantation. Ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

Heavily-doped (n+) n-type silicon carbide source regions 250 may be formed in upper portions of the p-wells 240 directly adjacent and contacting the more heavily doped portions 242 of the p-wells 240. The n-type source regions 250 may also be formed by ion implantation. The heavily-doped (n+) n-type silicon carbide regions 250 act as source regions for the unit cell transistor. The drift region 220, current spreading layer 230 and the substrate 210 together act as a common drain region for the power semiconductor device 100.

The n-type silicon carbide substrate 210, n-type silicon carbide drift region 220/current spreading layer 230, the p-wells 240, doped portions 242 and the n-type source regions 250 formed therein may together comprise a semiconductor structure of the semiconductor device 100.

A gate insulating pattern 260 may be on the upper surface of the semiconductor layer structure over the exposed portions of the current spreading layer 230 and extending onto the edges of the p-wells 240 and n-type source regions 250. The gate insulating pattern 260 may include, for example, a silicon oxide layer, although other insulating materials may be used. A gate finger 270 is on the gate insulating pattern 260. The gate finger 270 may correspond to one of the gate fingers 134 illustrated in FIG. 2B above. Accordingly, it will be appreciated that the gate finger 270 may be part of a continuous gate structure that includes the gate pad 132, one or more gate runners 136, and a plurality of gate fingers 270. In some embodiments, this gate structure may include, for example, a semiconductor pattern (e.g., polysilicon) or a metal gate pattern.

Source contacts 280 may be on the heavily-doped n-type source regions 250 and the more heavily-doped portions 242 of the p-wells. As described above with reference to FIGS. 2A-2B, the source contacts 280 may be part of a continuous source pattern 123 that extends across the upper surface of the silicon carbide semiconductor layer structure. The remainder of the source pattern 123 (as well as the insulating layer that electrically isolates the gate fingers 270 from the source pattern 123) is not shown in FIGS. 3A and 3B to simplify the drawings. The source contacts 280 may include, for example, metals such as nickel, titanium, tungsten or aluminum, or alloys or thin layered stacks of these or similar materials. As described above, a drain bond pad 124 (e.g., drain contact) may be on the lower surface of the substrate 210. The drain bond pad 124 may include, for example, similar materials to the source contact, as this forms an ohmic contact to the silicon carbide substrate. While the power semiconductor device 100 is an n-type device with the source contacts 280 on an upper surface thereof and the drain bond pad 124 on the bottom surface thereof, it will be appreciated that in p-type devices these locations are reversed.

Horizontal channel regions 272 are formed in the p-wells 240 adjacent to the gate insulating pattern 260. Current may flow from the n-type source regions 250 through the channel regions 272 to the portion of the drift region 220/current spreading layer 230 that is underneath the gate finger 270 when a voltage is applied to the gate fingers 270, as shown by the arrows in FIG. 3B.

FIG. 3B depicts a unit cell with a gate finger 270 formed on top of the semiconductor structure for purposes of illustration and discussion. Alternatively, the unit cell may have the gate finger 270 at least partially in a gate trench within the semiconductor structure. While the power semiconductor device 100 is an n-type device with the source contacts 280 on an upper surface thereof and the drain contact on the bottom surface thereof, it will be appreciated that in p-type devices these locations are reversed.

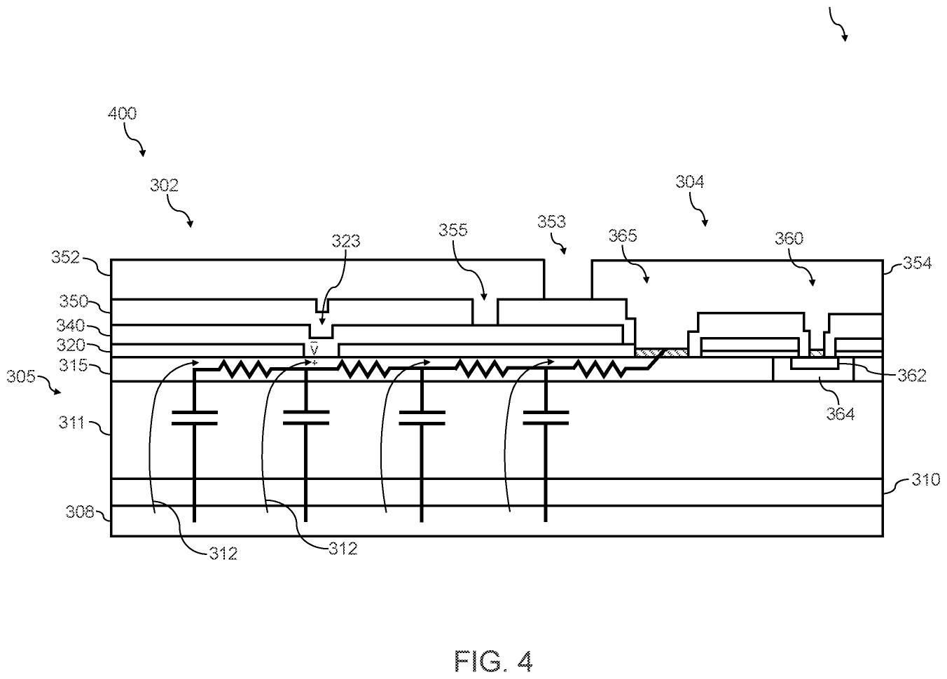

FIG. 4 depicts a cross-section of at least a portion of an example power semiconductor device 400. The power semiconductor device 400 includes a semiconductor structure 305. For instance, in some implementations, the semiconductor structure 305 can be a wide bandgap semiconductor structure. As one example, a wide bandgap semiconductor structure may include or be made of one or more wide bandgap semiconductor structures. A wide bandgap semiconductor may have a larger bandgap than conventional semiconductors, such as pure silicon or gallium arsenide. Example wide bandgap semiconductors include, but are not limited to, silicon carbide, gallium nitride, etc. As one example, in some implementations, the semiconductor structure 305 can include silicon carbide.

The semiconductor structure 305 can include a substrate 310. The substrate 310 can be a semiconductor substrate, such as a silicon carbide substrate. In some examples, the substrate 310 can have a first conductivity type. In some examples, the substrate 310 may include, for example, a single crystal 4H silicon carbide semiconductor substrate. The substrate 310 may be heavily-doped with n-type impurities (i.e., an n+ silicon carbide substrate). The impurities may comprise, for example, nitrogen or phosphorus. The doping concentration of the substrate 310 may be, for example, between 1×10¹⁸ atoms/cm³ and 1×10²¹ atoms/cm³, although other doping concentrations may be used. The substrate 310 may be any appropriate thickness (e.g., between about 100 and about 500 microns thick). Other suitable substrates may be used without deviating from the scope of the present disclosure, such as a silicon substrate, sapphire substrate, etc.

The semiconductor structure 305 may include a drift region 311 on the substrate 310. The semiconductor structure 305 may include a p-type doped region 315 on the drift region 311. The n-type silicon carbide drift region 311 may be formed by, for example, epitaxial growth on the silicon carbide substrate 310. The n-type silicon carbide drift region 311 may have, for example, a doping concentration of 1×10¹⁶ to 5×10¹⁷ dopants/cm³. The n-type silicon carbide drift region 311 may be a thick region, having a vertical height above the substrate 310 of, for example, about 3 to about 100 microns. The drift region 311 may be a voltage blocking semiconductor layer and may form a junction capacitance from the p-type doped region 315.

The power semiconductor device 300 can include an inactive region 302. For instance, the inactive region 302 may include a gate pad 352 and/or the regions of the semiconductor structure 305 substantially underneath the gate pad 352. The power semiconductor device 400 can additionally include an inner metal dielectric (IMD) layer 350. At least a portion of the IMD layer 350 can be between at least a portion of the gate pad 352 and the semiconductor structure 305 in the inactive region 302. A polysilicon gate layer 340 can further be included on the semiconductor structure 305 in the inactive region 302. The gate pad 352 can be coupled to the polysilicon gate layer 340 with at least one gate via 355. For instance, the gate via 355 can directly couple the polysilicon gate layer 340 to the gate pad 352 (e.g., without any intervening components). Furthermore, a p-type doped region 315 (e.g., a p-type doped silicon carbide region) of the semiconductor structure 305 can be located proximate the polysilicon gate layer 340. In the example of FIG. 4, a thick field insulating layer 320 isolates the semiconductor structure 305 from the polysilicon gate layer 340. The field insulating layer 320 includes a defect 323, resulting in a thinner-than-average portion of the field insulating layer 320 at the defect 323.

The power semiconductor device 400 can additionally include an active region 304 having a source contact 354. A drain contact 308 may be on the lower surface of the substrate 310. The drain contact 308 may include, for example, similar materials to the source contact 354, as this forms an ohmic contact to the substrate 310. A channel 353 can separate the source contact 354 from the gate pad 352. While the power semiconductor device 400 is an n-type device with the source contact 354 on an upper surface thereof and the drain contact 308 on the bottom surface thereof, it will be appreciated that in p-type devices these locations are reversed.

One or more shunt contact structures 365 can be formed between the semiconductor structure 305 and the source contact 354. The shunt contact structure 365 can provide a path for a displacement current 312 to pass from the drain contact 308 to the source contact 354 through the semiconductor structure 305 (e.g., in the inactive region 302 of the semiconductor structure 305). In some examples, the shunt contact structures 365 can include a silicide between the shunt contact structure 365 and the semiconductor structure 305. The shaded layer in the FIGS. on the shunt contact structures 365 or otherwise on a source contact (e.g., source vias 360) represents a silicide layer. Furthermore, the power semiconductor device 400 can include one or more source vias 360 configured to couple the source contact 354 to an n-type contact 362 and/or p-wells 364.

During a switching event over which the power semiconductor device 400 experiences a rapid change in voltage, a displacement current 312 can be induced in the semiconductor structure 305. As the displacement current 312 passes from the drain contact 308 to the source contact 354, the capacitive and/or resistive effects of the semiconductor structure 305 can create a voltage gradient (denoted by “V” in FIG. 4) between the polysilicon gate layer 340 and the source contact 354 (e.g., across the field insulating pattern 320). For instance, the semiconductor structure 305 may provide a capacitive effect (e.g., due to junction between the drift region 311 and p-type doped region 315) along the depth of the semiconductor structure 305 (e.g., towards the p-type doped region 315). Additionally, the semiconductor structure 305 (e.g., the p-type doped region 315) can provide a resistive effect as the displacement current 312 flows along the length of the semiconductor structure 305 towards the source contact 354. The flow of the displacement current 312 and the effects of the semiconductor structure 305 are illustrated in FIG. 4 using schematic resistors and capacitors, although it should be understood that these symbols are included to signify resistive and capacitive effects and not necessarily electronic components. Generally, the voltage gradient across the field insulating pattern 320 resulting from displacement current can increase at further distances from the source contact 354.

The field insulating layer 320 can generally prevent a breakdown condition where the magnitude of the voltage gradient induced by the displacement current 312 is great enough such that the displacement current 312 has sufficient potential to overcome the insulating effect of the field insulating layer 320 and cause breakdown of the field insulating layer 320. Under normal conditions, the field insulating layer 320 and/or a gate insulating layer (not illustrated) can provide sufficient insulating effect to prevent the displacement current 312 from flowing into the polysilicon gate layer 340 from the semiconductor structure 305. However, the portion of the field oxide layer 320 having the defect 323 can provide significantly reduced insulating effect between the semiconductor structure 305 and the polysilicon gate layer 340. In this case, the insulating effect at the point of the defect 323 may be insufficient to prevent the displacement current 312 from passing into the polysilicon gate layer 340, leading to a breakdown condition. This may irreparably damage the power semiconductor device 400 and/or other electronics and devices included in circuits with the power semiconductor device 400.

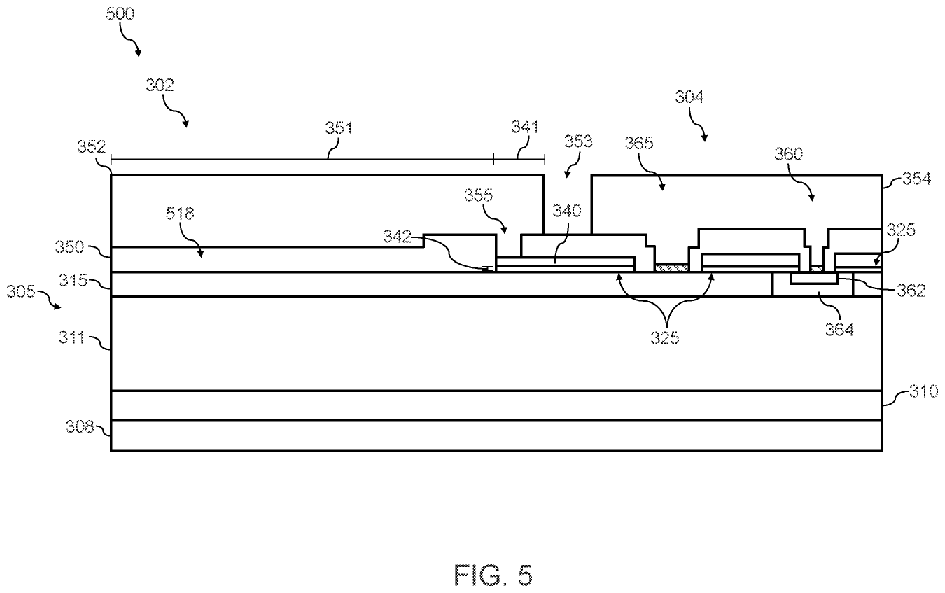

Example aspects of the present disclosure provide a technical solution to this problem. In particular, FIG. 5 depicts a cross-section of at least a portion of an example power semiconductor device 500 according to example embodiments of the present disclosure. The semiconductor device 500 includes a gate pad 352, a source contact 354, and a drain contact 308. The gate pad 352, the source contact 354, and the drain contact 308 can be configured to function as a gate, source, and drain, respectively, of a semiconductor device, such as a power MOSFET.

The power semiconductor device 500 includes a semiconductor structure 305. The semiconductor structure 305 includes a substrate 310, a drift region 311, and a p-type doped region 315. A drain contact 308 is on the substrate 310. A shunt contact structure 365 provides a path for a displacement current from the drain contact 308 to the source contact 354 through the semiconductor structure 305 in the inactive region 302. As a result of the shunt contact structure 365, the voltage levels induced by the semiconductor structure 305 attributable to displacement currents may be significantly reduced, allowing for significantly higher displacement currents without risking device failure.

The power semiconductor device 500 can additionally include an inner metal dielectric (IMD) layer 350. At least a portion of the IMD layer 350 can be between at least a portion of the gate pad 352 and the semiconductor structure 305 in the inactive region 302. In particular, in the power semiconductor device 500, the IMD layer 350 directly contacts (e.g., both) at least a portion of the gate pad 352 and at least a portion of the semiconductor structure 305 in the inactive region 302. For instance, the power semiconductor device 500 includes a region 518 where a first side of the IMD layer 350 directly contacts the gate pad 352 and a second side opposite the first side directly contacts the semiconductor structure 305 (e.g., the p-type doped region 315). The region 518 can be at least a portion of the inactive region 302.

The power semiconductor device 500 further includes a polysilicon gate layer 340. The polysilicon gate layer 340 may be vulnerable to damage if displacement current from the semiconductor structure 305 enters the polysilicon gate layer 340. The power semiconductor device 500 can include a gate insulating pattern 325 between the polysilicon gate layer 340 and the semiconductor structure 305. The gate insulating pattern 325 can insulate the polysilicon gate layer 340 from the semiconductor structure 305. For instance, the gate insulating pattern 325 can tolerate a voltage gradient across the gate insulating pattern 325 up to a rated tolerance, below which current may not flow through the gate insulating pattern 325.

Furthermore, the gate insulating pattern 325 can be relatively thin. For instance, in some implementations, the gate insulating pattern 325 can have a thickness such that the distance between the semiconductor structure 305 in the active region 302 and the polysilicon gate layer 340 is less than about 100 nm, such as less than about 50 nm, such as between about 1 nm and about 50 nm, such as between about 35 nm and about 50 nm. Furthermore, in some implementations, the thickness of the gate insulating pattern 325 between the polysilicon gate layer 340 and the semiconductor structure 305 in the inactive region 302 is substantially the same as a thickness of the gate insulating pattern 325 in an active region 304 of the power semiconductor device 500. For instance, the thickness may be the same between a gate finger 134 (not illustrated in FIG. 5) and the semiconductor structure 500. Furthermore, in some implementations, a distance 342 between the semiconductor structure 305 in the inactive region 302 and the polysilicon gate layer 340 through the gate insulating pattern 325 can be about 50 nm or less, such as between about 1 nm and about 50 nm, such as between 35 nm and 50 nm.

In some implementations, a barrier metal (e.g., TiN, Ti—TiN, Ti—TaN, etc.) may be between the gate insulating layer 325 and the polysilicon gate layer 340 to prevent penetration of contaminants, such as Al, AlCu, and so on, from the polysilicon gate layer 340 into the gate insulating layer 325. Including the barrier metal can prevent damage and defects to the gate insulating layer 325 during manufacturing, such as during a contact etch followed by wet etch process.

The power semiconductor device 500 may not include a field insulating layer 320 (FIG. 4). For instance, in the example of FIG. 5, there is no field insulating layer having a thickness of greater than about 100 nm between the polysilicon gate layer 340 and the semiconductor structure 305 in the inactive region 302 of the semiconductor structure 305. The omission of the field insulating layer can be achieved in part by including the polysilicon gate layer 340 in a region proximate the shunt contact structure 365.

According to aspects of the present disclosure, a voltage across the gat insulating pattern 325 can be maintained below a breakdown voltage of the gate insulating pattern 325. In particular, the voltage may spike during switching conditions (e.g., during large voltage changes at the contacts 308, 352, 354) or other transient conditions associated with transient displacement currents. According to example aspects of the present disclosure, the magnitude of a voltage across the gate insulating pattern 325 associated with the displacement current is such that the gate insulating electric field is less than about 8 MV/cm, such as in a range of about 1.5 MV/cm to about 7 MV/cm, such as in a range of about 5 MV/cm to about 6 MV/cm, such as less than about 5.7 MV/cm. For instance, during a switching condition or other transient condition inducing a displacement current, the electric field across the gate insulating pattern 325 may be maintained below about 8 MV/cm, such as in a range of about 1.5 MV/cm to about 7 MV/cm, such as between about 5 MV/cm and about 6 MV/cm, such as less than about 5.7 MV/cm. At this relatively low gate insulating electric field, the gate insulating pattern 325 can provide sufficient insulation to prevent breakdown of the gate insulating pattern 325 near the polysilicon gate layer 340 due to displacement current.

For instance, in some implementations, the polysilicon gate layer 340 can be located in a region proximate the shunt contact structure 365. As one example, in the example of FIG. 5, the polysilicon gate layer 340 can be limited to the region proximate the shunt contact structure 365, e.g., not included or located in a second region that is not proximate the shunt contact structure 365. As used herein, the polysilicon gate layer 340 may be proximate the shunt contact structure 365 if the polysilicon gate layer 340 is contained within a region within a certain radius of the shunt contact structure 365, such as a region approximately five times a radius of the shunt contact structure 365. As another example, the portion of the polysilicon gate layer 340 under the gate pad 352 may be limited. For instance, in some implementations, the polysilicon gate layer 340 may have an area that is less than about 25% of the area of the gate pad 352. As another example, as depicted in FIG. 5, the region 341 of the polysilicon gate layer 340 that is under the gate pad 352 may be substantially smaller (e.g., less than about 25% of) the area 351 of the gate pad 352 not including the polysilicon gate layer 340.

In particular, the polysilicon gate layer 340 may be located in a region proximate the shunt contact structure 365 such that the gate insulating electric field across the gate insulating pattern 325 resulting from the displacement current 312 (not illustrated in FIG. 5) can be less than about 8 MV/cm, such as in a range of about 1.5 MV/cm to about 7 MV/cm, such as in a range of about 5 MV/cm to about 6 MV/cm, such as less than about 5.7 MV/cm. For instance, the extent of the region 341 including the polysilicon gate layer 340 may be selected such that, under expected transient currents, the portion of the p-type doped region 315 under the region 341 does not induce a gate insulating electric field greater than about 8 MV/cm.

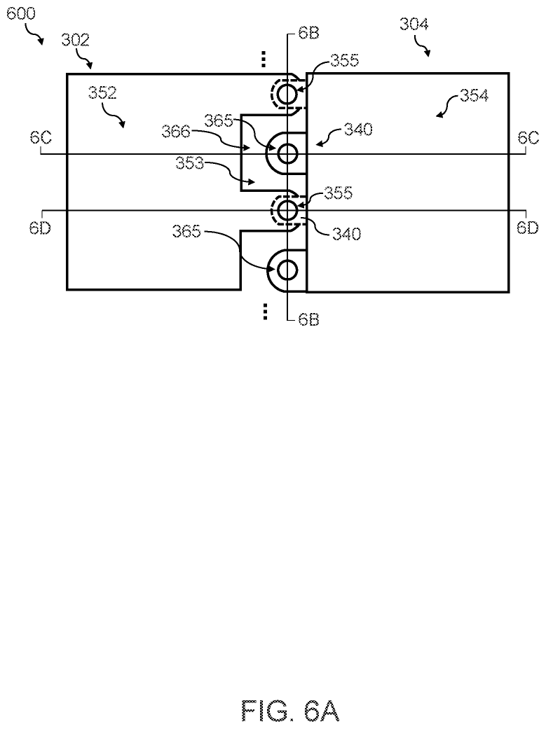

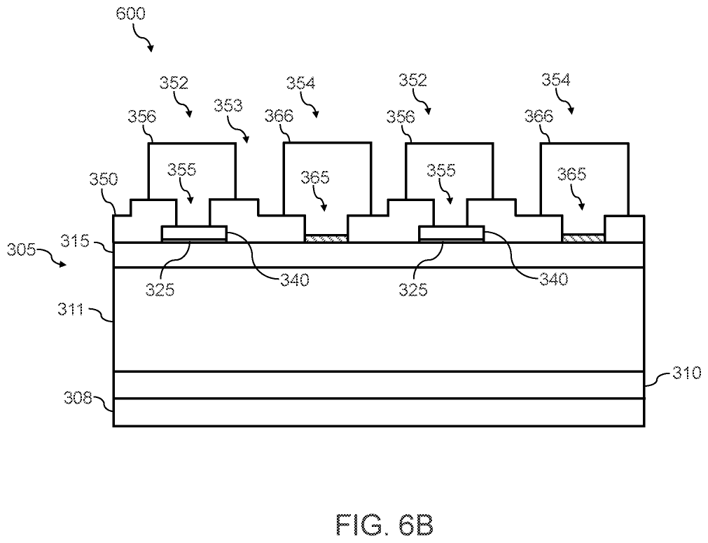

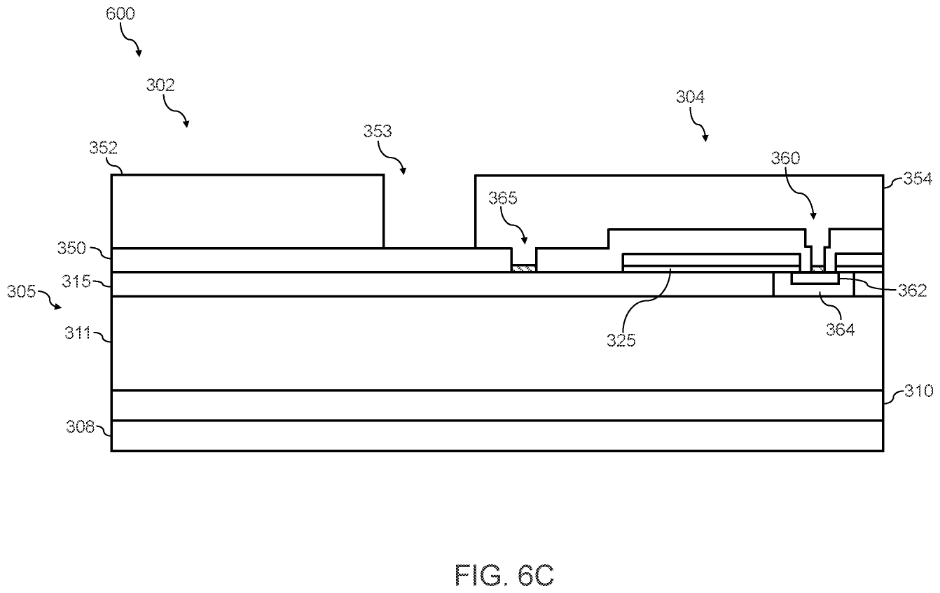

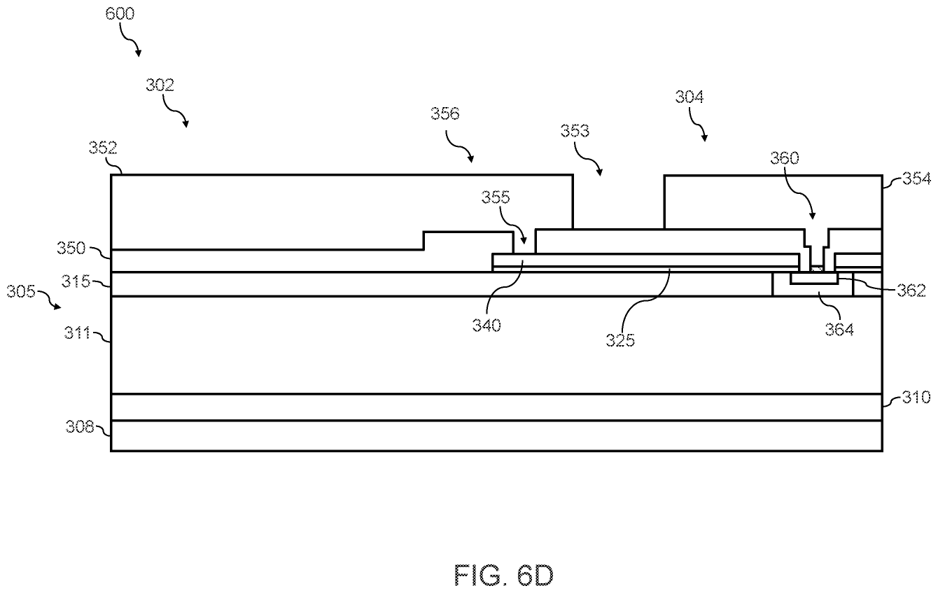

In some embodiments, the polysilicon gate layer 340 may be located in a region proximate the shunt contact structure 365 by including gate vias 355 and shunt contact structures 365 that are interdigitated. For instance, FIGS. 6A-6D depict views of an example power semiconductor device 600 including interdigitated vias according to example embodiments of the present disclosure. In particular, FIG. 6A depicts a top-down view of the power semiconductor device 600. In the power semiconductor device 600, the gate vias 355 and the shunt contact structures 365 are interdigitated. For instance, the gate vias and the shunt contact structures may be alternatingly aligned along a line or a direction. The line or direction can be, for example, a line or direction defined parallel to a substantial direction of the channel 353 (e.g., along the line 6B). An interdigitating portion 356 of the gate pad 352 may extend into the channel 353 to support the gate via 355. Similarly, an interdigitating portion 366 of the source contact 354 may extend into the channel 353 to support the shunt contact structure 365. As another example, centroids of the gate vias 355 and the shunt contact structures 365 may be substantially aligned along the direction.

FIG. 6B depicts a cross-section of the example power semiconductor device 600 of FIG. 6A along the line 6B, according to example embodiments of the present disclosure. In particular, FIG. 6B depicts a cross-section along the direction of interdigitation of the gate vias 355 and the shunt contact structures 365. Therefore, as illustrated in FIG. 6B, the gate vias 355 and the shunt contact structures 365 may be alternatingly positioned and aligned along the line 6B. Furthermore, as illustrated in FIG. 6B, the polysilicon gate layer 340 may be proximate the gate via 355 and may not be proximate the shunt contact structure 365.

FIG. 6C depicts a cross-section of the example power semiconductor device 600 of FIG. 6A along the line 6C, according to example embodiments of the present disclosure. In addition, FIG. 6D depicts a cross-section of at least a portion of the example power semiconductor device 600 of FIG. 6A along the line 6D, according to example embodiments of the present disclosure. As illustrated in the cross-sections of FIGS. 6C and 6D, only one of the gate vias 355 or the shunt contact structures 365 may be present in any given cross-section taken perpendicular to the direction of the interdigitated vias 355 and shunt contact structures 365 (e.g., along the line 6B). For instance, in the cross-section of FIG. 6C, only a shunt contact structure 365 is included and the gate via 355 is omitted. Similarly, in the cross-section of FIG. 6D, only a gate via 355 is included and the shunt contact structure 365 is omitted.

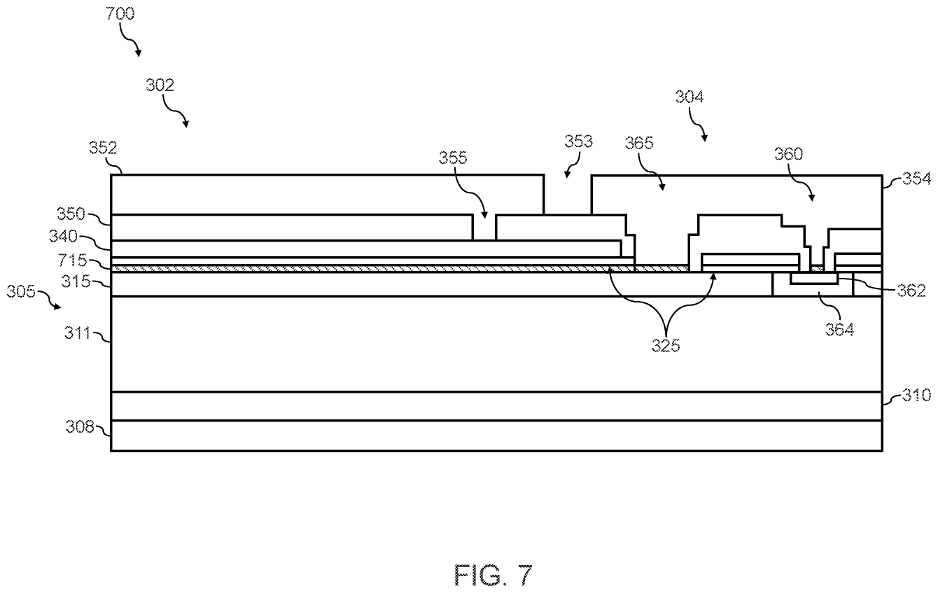

FIG. 7 depicts a cross-section of at least a portion of an example power semiconductor device 700 according to example embodiments of the present disclosure. The semiconductor device 700 includes a gate pad 352, a source contact 354, and a drain contact 308 coupled to a semiconductor structure 305 including a drift region 311 and a p-type doped region 315, as discussed with reference to FIGS. 4 and 5. The semiconductor structure 305 is on a substrate 310. Furthermore, the power semiconductor device 700 includes a polysilicon gate layer 340 adjacent to a gate insulating pattern 325 between the polysilicon gate layer 340 and the semiconductor structure 305, as discussed herein. The polysilicon gate layer 340 can have an area at least as great as about 75% of an area of the gate pad 352. For instance, in the example power semiconductor device 700, the polysilicon gate layer 340 is beneath substantially an entire surface of the gate pad 352, rather than being limited to a region proximate the shunt contact structure 365 as in the example power semiconductor device 500 of FIG. 5. Furthermore, the gate insulating pattern 325 correspondingly extends over the entire surface of the polysilicon gate layer 340.

In the example of FIG. 7, the power semiconductor device 700 includes a silicide 715 in the inactive region 302 contacting the gate insulating pattern 325. The silicide 715 can be between the p-type doped region 315 and the polysilicon gate layer 340. For instance, in some implementations, regions of the p-type doped region 315 may be metalized or “silicided” in order to significantly reduce their resistance. In some implementations, the gate insulating layer 325 may be deposited as a film (e.g., a high-temperature oxide film) to facilitate growing the gate insulating layer 325 over the metallic silicide 715. The reduced resistance can additionally reduce the magnitude of the voltage gradients induced by the p-type doped region 315 as a result of transient currents or displacement currents. In this manner, the magnitude of the gate insulating electric field resulting from displacement currents can be reduced to less than about 8 MV/cm., even at portions of the polysilicon gate layer 340 that are far from the shunt contact structure 365, such as on an opposite end of gate pad 352 from the shunt contact structure 365.

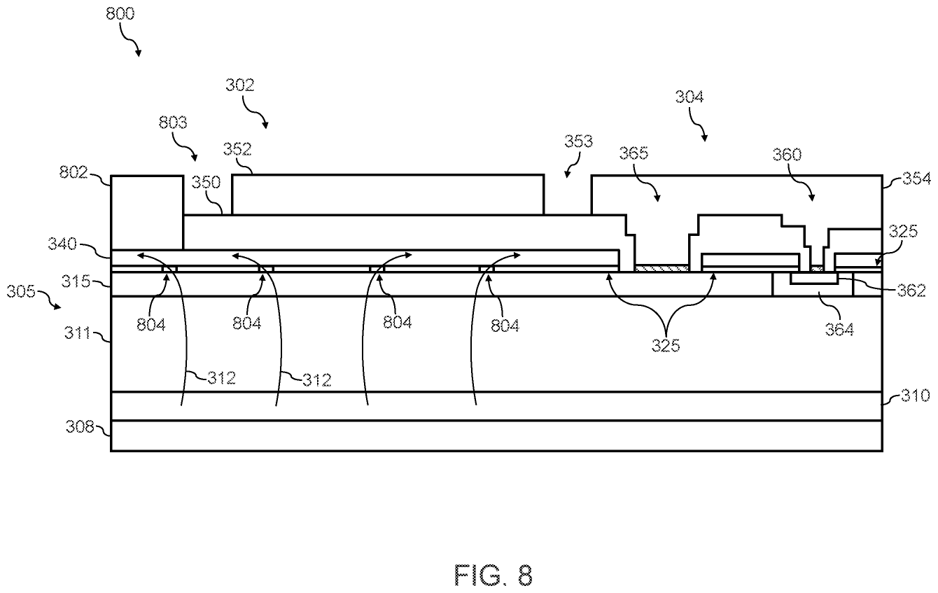

FIG. 8 depicts a cross-section of at least a portion of an example power semiconductor device 800 according to example embodiments of the present disclosure. The semiconductor device 800 includes a gate pad 352, a source contact 354, and a drain contact 308 coupled to a semiconductor structure 305 including a drift region 311 and a p-type doped region 315, as discussed with reference to FIGS. 4 and 5. The semiconductor structure 305 is on a substrate 310. Furthermore, the power semiconductor device 800 includes a polysilicon gate layer 340 adjacent to a gate insulating pattern 325 between the polysilicon gate layer 340 and the semiconductor structure 305, as discussed herein. The polysilicon gate layer 340 can have an area at least as great as about 75% of an area of the gate pad 352. For instance, in the example power semiconductor device 800, the polysilicon gate layer 340 is beneath substantially an entire surface of the gate pad 352, rather than being limited to a region proximate the shunt contact structure 365 as in the example power semiconductor device 500 of FIG. 5. Furthermore, the gate insulating pattern 325 correspondingly extends over the entire surface of the polysilicon gate layer 340.

The power semiconductor device 800 further includes a source bus 802. The source bus 802 can be proximate the gate pad 352 and/or the IMD layer 350. However, the source bus 802 may not overlap the gate pad 352 or the IMD layer 350. The source bus 802 may be coupled to the polysilicon gate layer 340 in some embodiments. For instance, in some implementations, the source bus 802 may directly contact the polysilicon gate layer 340. In some implementations, the source bus 802 can be overlapping the semiconductor structure 305 in the inactive region. For instance, the source bus 802 may at least partially overlap at least a portion of the semiconductor structure 305 in a direction defined by a depth of the semiconductor device 800.

Furthermore, the gate insulating pattern 325 of the power semiconductor device 800 includes a plurality of holes 804. The holes 804 may include portions the polysilicon gate layer 340 and/or another material. The holes 804 can provide a conductive path for displacement current to the source bus 802. The conductive path can connect (e.g., electrically connect) the semiconductor structure 305 with the polysilicon gate layer 340. In this manner, the displacement current 312 induced in the semiconductor structure 305 may flow through the conductive path and into the source bus 802. For instance, the polysilicon gate layer 340 can provide relatively low resistance for the displacement current 312. As one example, the holes 804 can provide that the polysilicon gate layer 340 forms a heterojunction with the p-type doped region 315, providing a low resistance path for the displacement current 312 to be collected by the source bus 802 without generating significant voltage gradients or high electric fields.

The source bus 802 may be coupled to the source or otherwise configured to remove the displacement current 312 without damaging the polysilicon gate layer 340 or the power semiconductor device 800. As one example, the source bus 802 can be coupled to a source connection. The polysilicon gate layer 340 may therefore be maintained at or near the potential of the source. The source bus 802 and the conductive path from the holes 804 may provide that the displacement current 312 does not flow through enough of the semiconductor structure 305 to induce a voltage gradient with a magnitude great enough, for instance, to exceed about 20 volts. For instance, the greatest magnitude of the voltage gradient may be limited by the source bus 802 and conductive path such that the magnitude is less than, for instance, about 5 volts. As a result, a gate insulating electric field is less than about 8 MV/cm, such as in a range of about 1.5 MV/cm to about 7 MV/cm. such as in a range of about 5 MV/cm to about 6 MV/cm, such as less than about 5.7 MV/cm.

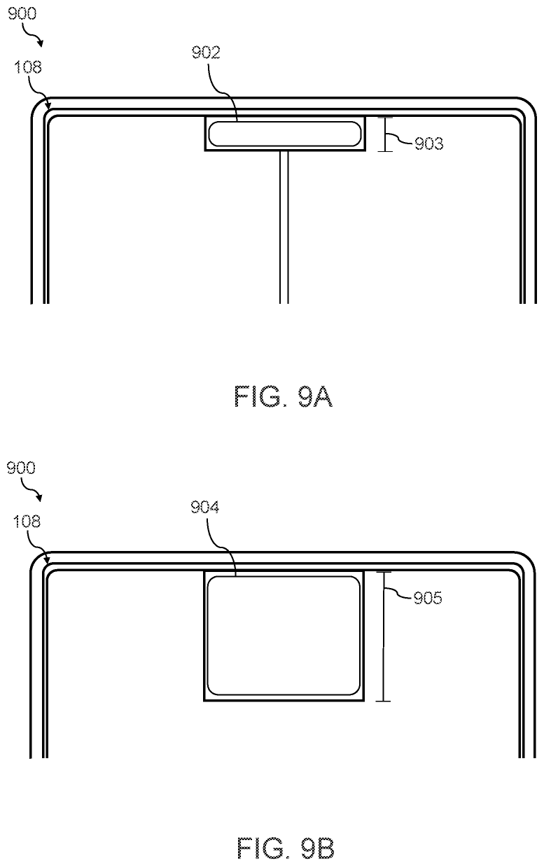

FIGS. 9A-9B depict an example power semiconductor device 900 according to example embodiments of the present disclosure. In particular, FIGS. 9A-9B depict a top-down view of the power semiconductor device. The power semiconductor device 900 includes a multilayer gate pad metal structure on the polysilicon gate layer 340. The multilayer gate pad metal structure includes a first gate metal layer 902 (depicted in FIG. 9A) and a second gate metal layer 904 (depicted in FIG. 9B). The first metal gate layer 902 can be coupled to the polysilicon gate layer 340. For instance, the first metal gate layer 902 may overlap at least a portion of the polysilicon gate layer 340. The second gate metal layer 904 can at least partially overlap the first gate metal layer. In some implementations, an insulating layer can be between the first gate metal layer 902 and the second gate metal layer 904.

According to example aspects of the present disclosure, an area of the first metal gate layer 902 (e.g., corresponding to an area of the polysilicon gate layer 340) can be less than an area of the second gate metal layer 904. For instance, the second gate metal layer 904 may form the contact area of the gate pad 352 to which other devices may be coupled. The second gate metal layer 904 may have a length 905 that is greater than a length 903 of the first gate metal layer 902. The greater length 905 may facilitate easier coupling of devices to the second gate metal layer 904. Additionally, the lesser length 903 of the first metal gate layer 902 and, correspondingly, the polysilicon gate layer 340, may limit the magnitude of the voltage gradient and electric fields across the gate insulating pattern induced by switching currents.

One example aspect of the present disclosure is directed to a power semiconductor device. The power semiconductor device includes a semiconductor structure. The power semiconductor device further includes a polysilicon gate layer on the semiconductor structure in an inactive region of the semiconductor device. The power semiconductor device further includes a gate insulating pattern between the polysilicon gate layer and the semiconductor structure, the gate insulating pattern having a thickness such that a distance between the semiconductor in the inactive region and the polysilicon gate layer through the gate insulating pattern is less than about 100 nm. The power semiconductor device further includes a shunt contact structure on semiconductor structure in the inactive region, the shunt contact structure providing a path for a displacement current from a drain contact to a source contact through the semiconductor structure in the inactive region. The gate insulating electric field across the gate insulating pattern associated with the displacement current is less than about 8 MV/cm.

In some examples, there is no field insulating layer having a thickness of greater than about 100 nm between the polysilicon gate layer and the semiconductor structure in the inactive region of the semiconductor structure.

In some examples, the polysilicon gate layer is located in a region proximate the shunt contact structure such that the gate insulating electric field resulting from the displacement current is less than about 8 MV/cm.

In some examples, the power semiconductor device may further include a gate pad coupled to the polysilicon gate layer with at least one gate via, wherein the polysilicon gate layer has an area that is less than about 25% of an area of the gate pad.

In some examples, the power semiconductor device comprises a plurality of gate vias and a plurality of shunt contact structures, wherein the plurality of gate vias and the plurality of shunt contact structures are interdigitated.

In some examples, the power semiconductor device may further include an inter metal dielectric (IMD) layer between at least a portion of the gate pad and the semiconductor structure in the inactive region.

In some examples, the IMD layer directly contacts at least a portion of the gate pad and at least a portion of the semiconductor structure in the inactive region.

In some examples, a thickness of the gate insulating pattern between the polysilicon gate layer and the semiconductor structure in the inactive region is substantially the same as a thickness of a gate insulating pattern in an active region of the semiconductor device between a gate finger and the semiconductor structure.

In some examples, the device comprises a silicide in the inactive region contacting the gate insulating pattern.

In some examples, the power semiconductor device may further include a source bus coupled to the polysilicon gate layer, the gate insulating pattern comprising one or more holes, each hole comprising providing a conductive path for displacement current to the source bus through the polysilicon gate layer in the inactive region.

In some examples, the power semiconductor device includes a multilayer gate pad metal structure on the polysilicon gate layer. The multilayer gate pad metal structure may include a first gate metal layer coupled to the polysilicon gate layer. The multilayer gate pad metal structure may further include a second gate metal layer at least partially overlapping the first gate metal layer. The multilayer gate pad metal structure may further include an insulating layer between the first gate metal layer and the second gate metal layer. An area of the polysilicon gate layer is less than an area of the second gate metal layer.

In some examples, a distance between the semiconductor structure in the inactive region and the polysilicon gate layer through the gate insulating pattern is less than about 50 nm.

In some examples, the semiconductor structure is a wide bandgap semiconductor structure.

In some examples, the wide bandgap semiconductor structure comprises silicon carbide.

In some examples, the power semiconductor device is a MOSFET.

Another example aspect of the present disclosure is directed to a power semiconductor device. The power semiconductor device includes a semiconductor structure. The power semiconductor device further includes a polysilicon gate layer on the semiconductor structure in an inactive region of the power semiconductor device. The power semiconductor device further includes a gate pad coupled to the polysilicon gate layer. The power semiconductor device further includes an inter metal dielectric (IMD) layer between at least a portion of a gate pad and the semiconductor structure in the inactive region. The IMD layer directly contacts at least a portion of the gate pad and at least a portion of the semiconductor structure in the inactive region.

In some examples, the power semiconductor device further includes a gate insulating pattern in the inactive region between the polysilicon gate layer and the semiconductor structure.

In some examples, a thickness of the gate insulating pattern between the polysilicon gate layer and the semiconductor structure in the inactive region is substantially the same as a thickness of a gate insulating pattern in an active region of the semiconductor device between a gate finger and the semiconductor structure.

In some examples, there is no field insulating layer having a thickness of greater than about 100 nm between the polysilicon gate layer and the semiconductor structure in the inactive region of the semiconductor structure.

In some examples, the power semiconductor device further includes a shunt contact structure on semiconductor structure in the inactive region, the shunt contact structure providing a path for a displacement current from a drain contact to a source contact through the semiconductor structure in the inactive region, wherein the polysilicon gate layer is located in a region proximate a shunt contact structure such that the gate insulating electric field resulting from the displacement current is less than about 8 MV/cm.

In some examples, the power semiconductor device further includes a gate pad coupled to the polysilicon gate layer with at least one gate via, wherein the polysilicon gate layer has an area that is less than about 25% of an area of the gate pad.

In some examples, a distance between the semiconductor structure in the inactive region and the polysilicon gate layer through the gate insulating pattern is less than about 50 nm.

In some examples, the semiconductor structure is a wide bandgap semiconductor structure.

In some examples, the wide bandgap semiconductor structure comprises silicon carbide.

In some examples, the power semiconductor device is a MOSFET.

Another example aspect of the present disclosure is directed to a power semiconductor device. The power semiconductor device includes a semiconductor structure, wherein a portion of the semiconductor structure is in an inactive region of the power semiconductor device. The power semiconductor device further includes a polysilicon gate layer on the semiconductor structure in the inactive region. The power semiconductor device further includes a gate insulating pattern between the polysilicon gate layer and the semiconductor structure in the inactive region. The power semiconductor device further includes a shunt contact structure on semiconductor structure, the shunt contact structure providing a path for a displacement current from a drain contact to a source contact. The polysilicon gate layer is located in a region proximate the shunt contact structure such that a gate insulating electric field resulting from the displacement current is less than about 8 MV/cm.

In some examples, there is no field insulating layer having a thickness of greater than about 100 nm between the polysilicon gate layer and the semiconductor structure.

In some examples, the power semiconductor device further includes a gate pad electrically coupled to the polysilicon gate layer.

In some examples, the power semiconductor device further includes a gate via electrically coupling the gate pad with the polysilicon gate layer.

In some examples, the polysilicon gate layer has an area that is less than about 25% of an area of the gate pad.

In some examples, the power semiconductor device comprises a plurality of gate vias and a plurality of shunt contact structures, wherein the plurality of gate vias and the plurality of shunt contact structures are interdigitated.

In some examples, the power semiconductor device further includes an inter metal dielectric (IMD) layer between at least a portion of the gate pad and the semiconductor structure in the inactive region.

In some examples, the IMD layer directly contacts at least a portion of the gate pad and at least a portion of the semiconductor structure in the inactive region.

In some examples, the power semiconductor device includes a multilayer gate pad metal structure on the polysilicon gate layer. The multilayer gate pad metal structure may include a first gate metal layer coupled to the polysilicon gate layer. The multilayer gate pad metal structure may further include a second gate metal layer at least partially overlapping the first gate metal layer. The multilayer gate pad metal structure may further include an insulating layer between the first gate metal layer and the second gate metal layer. An area of the polysilicon gate layer is less than an area of the second gate metal layer.

In some examples, a distance between the semiconductor structure and the polysilicon gate layer through the gate insulating pattern is less than about 50 nm.

In some examples, the semiconductor structure comprises silicon carbide.

In some examples, the power semiconductor device is a MOSFET.

Another example aspect of the present disclosure is directed to a power semiconductor device. The power semiconductor device includes a semiconductor structure. The power semiconductor device further includes a polysilicon gate layer in an inactive region of the power semiconductor device. The power semiconductor device further includes a gate insulating pattern between the polysilicon gate layer and the semiconductor structure in the inactive region. The semiconductor structure comprises a silicide contacting the gate insulating pattern in the inactive region.

In some examples, there is no field insulating layer having a thickness of greater than about 100 nm between the semiconductor structure and the polysilicon gate layer.

In some examples, the silicide is on a p-type doped silicon carbide region.

In some examples, the silicide is between the p-type doped silicon carbide region and the polysilicon gate layer.

In some examples, the power semiconductor device further includes a gate pad coupled to the polysilicon gate layer.

In some examples, the polysilicon gate layer has an area at least as great as about 75% of an area of the gate pad.

In some examples, the power semiconductor device further includes a shunt contact structure, the shunt contact structure providing a path for a displacement current from a drain contact to a source contact through the semiconductor structure.

In some examples, a distance between the semiconductor structure and the polysilicon gate layer through the gate insulating pattern is less than about 50 nm.

In some examples, the semiconductor structure comprises silicon carbide.

In some examples, the power semiconductor device is a MOSFET.

Another example aspect of the present disclosure is directed to a power semiconductor device. The power semiconductor device includes a semiconductor structure. The power semiconductor device further includes a polysilicon gate layer. The power semiconductor device further includes a gate insulating pattern between the polysilicon gate layer and the semiconductor structure. The power semiconductor device further includes a source bus coupled to the polysilicon gate layer. The gate insulating pattern comprises a plurality of holes. A conductive path in one or more of the plurality of holes connecting the semiconductor structure with the polysilicon gate layer.

In some examples, there is no field insulating layer having a thickness of greater than about 100 nm between the semiconductor structure and the polysilicon gate layer.

In some examples, a thickness of the gate insulating pattern between the polysilicon gate layer and the semiconductor structure is substantially the same as a thickness of a gate insulating pattern between a gate finger and the semiconductor structure.

In some examples, the power semiconductor device further includes a gate pad coupled to the polysilicon gate layer.

In some examples, the polysilicon gate layer has an area at least as great as about 75% of an area of the gate pad.

In some examples, the source bus is overlapping the semiconductor structure.

In some examples, the power semiconductor device further includes a shunt contact structure on the semiconductor structure.

In some examples, the shunt contact structure provides a path for a displacement current from a drain contact to a source contact.

In some examples, a distance between the semiconductor structure and the polysilicon gate layer through the gate insulating pattern is less than about 50 nm.

In some examples, the semiconductor structure comprises silicon carbide.

In some examples, the power semiconductor device is a MOSFET.

Another example aspect of the present disclosure is directed to a power semiconductor device. The power semiconductor device includes a semiconductor structure. The power semiconductor device further includes a polysilicon gate layer. The power semiconductor device further includes a gate insulating pattern between the polysilicon gate layer and the semiconductor structure. The power semiconductor device further includes a shunt contact structure, the shunt contact structure providing a path for a displacement current from a drain contact to a source contact. There is no field insulating layer having a thickness of greater than 100 nm between the polysilicon gate layer and the semiconductor structure.

In some examples, the gate insulating pattern has a thickness of less than about 100 nm.

In some examples, the power semiconductor device further includes a gate pad coupled to the polysilicon gate layer.

In some examples, a distance between the semiconductor structure and the polysilicon gate layer through the gate insulating pattern is less than about 50 nm.

In some examples, the semiconductor structure comprises silicon carbide.

In some examples, the power semiconductor device is a MOSFET.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor device, comprising:
a semiconductor structure;
a polysilicon gate layer on the semiconductor structure in an inactive region of the semiconductor device;
a gate insulating pattern between the polysilicon gate layer and the semiconductor structure, the gate insulating pattern having a thickness such that a distance between the semiconductor in the inactive region and the polysilicon gate layer through the gate insulating pattern is less than about 100 nm;
a shunt contact structure on semiconductor structure in the inactive region, the shunt contact structure providing a path for a displacement current from a drain contact to a source contact through the semiconductor structure in the inactive region; and
wherein a gate insulating electric field across the gate insulating pattern associated with the displacement current is less than about 8 MV/cm.

2. The power semiconductor device of claim 1, wherein there is no field insulating layer having a thickness of greater than about 100 nm between the polysilicon gate layer and the semiconductor structure in the inactive region of the semiconductor structure.

3. The power semiconductor device of claim 1, wherein the polysilicon gate layer is located in a region proximate the shunt contact structure such that the gate insulating electric field resulting from the displacement current is less than about 8 MV/cm.

4. The power semiconductor device of claim 1, further comprising a gate pad coupled to the polysilicon gate layer with at least one gate via, wherein the polysilicon gate layer has an area that is less than about 25% of an area of the gate pad.

5. The power semiconductor device of claim 4, wherein the power semiconductor device comprises a plurality of gate vias and a plurality of shunt contact structures, wherein the plurality of gate vias and the plurality of shunt contact structures are interdigitated.

6. The power semiconductor device of claim 1, further comprising an inter metal dielectric (IMD) layer between at least a portion of the gate pad and the semiconductor structure in the inactive region.

7. The power semiconductor device of claim 6, wherein the IMD layer directly contacts at least a portion of the gate pad and at least a portion of the semiconductor structure in the inactive region.

8. The power semiconductor device of claim 1, wherein a thickness of the gate insulating pattern between the polysilicon gate layer and the semiconductor structure in the inactive region is substantially the same as a thickness of a gate insulating pattern in an active region of the semiconductor device between a gate finger and the semiconductor structure.

9. The power semiconductor device of claim 1, wherein the device comprises a silicide in the inactive region contacting the gate insulating pattern.

10. The power semiconductor device of claim 1, further comprising a source bus coupled to the polysilicon gate layer, the gate insulating pattern comprising one or more holes, each hole comprising providing a conductive path for displacement current to the source bus through the polysilicon gate layer in the inactive region.

11. The power semiconductor device of claim 1, wherein the power semiconductor device comprises a multilayer gate pad metal structure on the polysilicon gate layer, the multilayer gate pad metal structure comprising:
a first gate metal layer coupled to the polysilicon gate layer;
a second gate metal layer at least partially overlapping the first gate metal layer;
an insulating layer between the first gate metal layer and the second gate metal layer; and
wherein an area of the polysilicon gate layer is less than an area of the second gate metal layer.

12. The power semiconductor device of claim 1, wherein a distance between the semiconductor structure in the inactive region and the polysilicon gate layer through the gate insulating pattern is less than about 50 nm.

13. The power semiconductor device of claim 1, wherein the semiconductor structure is a wide bandgap semiconductor structure.

14. The power semiconductor device of claim 13, wherein the wide bandgap semiconductor structure comprises silicon carbide.

15. The power semiconductor device of claim 1, wherein the power semiconductor device is a MOSFET.

16. A power semiconductor device, comprising:
a semiconductor structure;
a polysilicon gate layer on the semiconductor structure in an inactive region of the power semiconductor device;
a gate pad coupled to the polysilicon gate layer;
an inter metal dielectric (IMD) layer between at least a portion of a gate pad and the semiconductor structure in the inactive region; and
wherein the IMD layer directly contacts at least a portion of the gate pad and at least a portion of the semiconductor structure in the inactive region.

17. The power semiconductor device of claim 16, further comprising a gate insulating pattern in the inactive region between the polysilicon gate layer and the semiconductor structure.

18. The power semiconductor device of claim 17, wherein a thickness of the gate insulating pattern between the polysilicon gate layer and the semiconductor structure in the inactive region is substantially the same as a thickness of a gate insulating pattern in an active region of the semiconductor device between a gate finger and the semiconductor structure.

19. The power semiconductor device of claim 16, wherein there is no field insulating layer having a thickness of greater than about 100 nm between the polysilicon gate layer and the semiconductor structure in the inactive region of the semiconductor structure.

20.-58. (canceled)

59. A power semiconductor device, comprising:
a semiconductor structure;
a polysilicon gate layer;
a gate insulating pattern between the polysilicon gate layer and the semiconductor structure;
a shunt contact structure, the shunt contact structure providing a path for a displacement current from a drain contact to a source contact; and
wherein there is no field insulating layer having a thickness of greater than 100 nm between the polysilicon gate layer and the semiconductor structure.

60.-64. (canceled)
